(19) United States
(12) Patent Application Publication
(10) Pub. No.: US 2015/0108491 A1
(43) Pub. Date: Apr. 23, 2015

(54) LIGHT EMITTING DIODE PACKAGE

(71) Applicant: Lextar Electronics Corporation, Hsinchu (TW)

(72) Inventor: Yu-Hsin LU, Dacun Township (TW)

(73) Assignee: Lextar Electronics Corporation, Hsinchu (TW)

(21) Appl. No.: 14/189,105

(22) Filed: Feb. 25, 2014

(30) Foreign Application Priority Data
Oct. 21, 2013 (TW) 102137925

(51) Int. Cl. H01L 33/50; H01L 33/60; H01L 33/32

(52) U.S. Cl. CPC H01L 33/50; H01L 33/32; H01L 33/60
USPC 257/76; 257/98

(57) ABSTRACT

A light emitting diode package includes a lead frame, a light emitting diode chip, a wavelength conversion structure, and a filter. The light emitting diode chip is disposed on and electrically connected to the lead frame for providing a first light beam with a first wavelength. The light emitting diode chip is configured to provide a first light beam with a first wavelength. The wavelength conversion structure is disposed on the light emitting diode chip, and is configured to convert the first light beam into a second light beam with a second wavelength. The filter is disposed between the light emitting diode chip and the wavelength conversion structure. The filter allows the first light beam from the light emitting diode chip to pass therethrough to enter the wavelength conversion structure, and reflects the second light beam from the wavelength conversion structure back to the wavelength conversion structure.

### RELATED APPLICATIONS

This application claims priority to Taiwan Application Serial Number 102137925, filed Oct. 21, 2013, which is herein incorporated by reference.

### BACKGROUND

1. Field of Invention

The present invention relates to a light emitting diode package.

2. Description of Related Art

In general, a light emitting diode chip may collocate with a wavelength conversion structure, the wavelength of light provided by can be converted into another wavelength. Light emitting diodes having different light colors can be achieved either by providing converted light or by providing converted light mixing with non-converted light.

However, since the light emitting diode chip may absorb light with a specific wavelength, the light converted by the wavelength conversion structure may be absorbed by the light emitting diode chip if being reflected back to the light emitting diode chip, thus causing the wavelength conversion structure to have a conversion efficiency loss, also lowering the total light emitting quantity of the light emitting diode may be reduced.

### SUMMARY

An aspect of the present invention provides a light emitting diode package including a lead frame, a light emitting diode chip, a wavelength conversion structure, and a filter. The light emitting diode chip is disposed on and electrically connected to the lead frame. The light emitting diode chip is configured to provide a first light beam with a first wavelength. The wavelength conversion structure is disposed on the light emitting diode chip configured to convert the first light beam into a second light beam with a second wavelength. The filter is disposed between the light emitting diode chip and the wavelength conversion structure. The filter allows the first light beam from the light emitting diode chip to pass therethrough to enter the wavelength conversion structure, and reflects the second light beam from the wavelength conversion structure back to the wavelength conversion structure.

In one or more embodiments, the light emitting diode chip is a flip chip.

In one or more embodiments, the filter is a distributed Bragg reflector (DBR). The distributed Bragg reflector includes a plurality of first dielectric layers and a plurality of second dielectric layers alternately stacked on each other. A reflective index of the first dielectric layers is greater than that of the second dielectric layers. The distributed Bragg reflector is connected adjacent to the light emitting diode chip via the first dielectric layer, and is connected adjacent to the wavelength conversion structure via the second dielectric layer. The reflective index of the first dielectric layers is greater than that of the light emitting diode chip, and the reflective index of the second dielectric layers is smaller than that of the wavelength conversion structure.

In one or more embodiments, the first dielectric layer and the second dielectric layer are formed from titanium dioxide (TiO₂), silicon dioxide (SiO₂), tantalum pentoxide (Ta₂O₅), silicon nitride (SiNₓ), or any combination thereof.

In one or more embodiments, the light emitting diode chip includes a sapphire substrate, and the reflective index of the first dielectric layer is greater than that of the sapphire substrate.

In one or more embodiments, the light emitting diode chip includes a gallium nitride layer, and the reflective index of the first dielectric layer is greater than that of the gallium nitride layer.

In one or more embodiments, the first wavelength is smaller than 500 nm, and the second wavelength is greater than 500 nm.

In one or more embodiments, the light emitting diode package further includes an encapsulant covering the light emitting diode chip, the wavelength conversion structure, and the filter.

In one or more embodiments, the wavelength conversion structure includes a main body and a plurality of wavelength conversion particles distributed in the main body.

In one or more embodiments, the main body is formed from silicon oxide inorganic compound, polycarbonate (PC), polyethylene terephthalate (PET), or any combination thereof.

Another aspect of the present invention provides a light emitting diode package including a lead frame, a light emitting diode chip, an encapsulant, a wavelength conversion structure, and a filter. The light emitting diode chip is disposed on and electrically connected to the lead frame. The light emitting diode chip is configured to provide a first light beam with a first wavelength. The encapsulant covers the light emitting diode chip. The wavelength conversion structure is disposed above the encapsulant for converting the first light beam into a second light beam with a second wavelength. The filter is disposed between the encapsulant and the wavelength conversion structure. The filter allows the first light beam from the light emitting diode chip to pass therethrough to enter the wavelength conversion structure, and reflects the second light beam from the wavelength conversion structure back to the wavelength conversion structure.

In one or more embodiments, the light emitting diode chip is a face up chip or a vertical chip.

In one or more embodiments, the filter is a distributed Bragg reflector (DBR). The distributed Bragg reflector includes a plurality of first dielectric layers and a plurality of second dielectric layers alternately stacked on each other. A reflective index of the first dielectric layers is greater than that of the second dielectric layers. The distributed Bragg reflector is connected adjacent to the encapsulant via the first dielectric layer, and is connected adjacent to the wavelength conversion structure via the second dielectric layer. The reflective index of the first dielectric layers is greater than that of the encapsulant, and the reflective index of the second dielectric layers is smaller than that of the wavelength conversion structure.

In one or more embodiments, the first and the second dielectric layers are made of titanium dioxide (TiO₂), silicon dioxide (SiO₂), tantalum pentoxide (Ta₂O₅), silicon nitride (SiNₓ), or any combination thereof.

In one or more embodiments, the first wavelength is smaller than 500 nm, and the second wavelength is greater than 500 nm.

In one or more embodiments, the wavelength conversion structure includes a main body and a plurality of wavelength conversion particles distributed in the body.

In one or more embodiments, the main body is made of silicon oxide inorganic compound, polycarbonate (PC), polyethylene terephthalate (PET), or any combination thereof.

Since the filter allows the first light beam to pass therethrough and reflects the second light beam, the filter can prevent the second light beam from entering the light emitting diode chip which may absorb the second light beam without blocking the first light beam from entering the wavelength conversion structure.

### BRIEF DESCRIPTION OF THE DRAWINGS

FIG. 1 is a cross-sectional view of a light emitting diode package according to an embodiment of the present invention;

FIG. 2 is a locally enlarged diagram of a light emitting diode chip, a wavelength conversion structure, and a filter shown in FIG. 1 according to one embodiment;

FIG. 3 is a locally enlarged diagram of the light emitting diode chip, the wavelength conversion structure, and the filter shown in FIG. 1 according to another embodiment;

FIG. 4 is a cross-sectional view of a light emitting diode package according to another embodiment of the present invention;

FIG. 5 is a cross-sectional view of a light emitting diode package according to another embodiment of the present invention; and

FIG. 6 is a locally enlarged diagram of an encapsulant, a wavelength conversion structure, and a filter of FIG. 4 or 5.

### DETAILED DESCRIPTION

Reference will now be made in detail to the present embodiments of the invention, examples of which are illustrated in the accompanying drawings. It is to be understood that the following disclosure provides many different embodiments, or examples, for implementing different features of the invention. Specific examples of components and arrangements are described below to simplify the present disclosure. These are, of course, merely examples and are not intended to be limiting. That is, some details are optional for some embodiment of this invention. Moreover, in order to simplify the drawings, some conventional structures and components is illustrated in a simple schematic form.

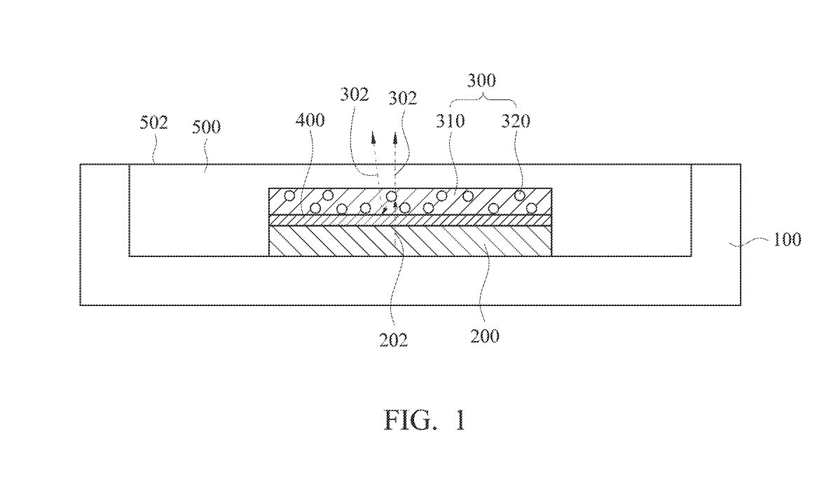

FIG. 1 is a cross-sectional view of a light emitting diode package according to an embodiment of the present invention. The light emitting diode package includes a lead frame 100, a light emitting diode chip 200, a wavelength conversion structure 300, and a filter 400. The light emitting diode chip 200 is disposed on and electrically connected to the lead frame 100. The light emitting diode chip 200 is configured to provide a first light beam 202 with a first wavelength. The wavelength conversion structure 300 is disposed on the light emitting diode chip 200 and is configured to convert the first light beam 202 into a second light beam 302 with a second wavelength. The filter 400 is disposed between the light emitting diode chip 200 and the wavelength conversion structure 300. The filter 400 allows the first light beam 202 from the light emitting diode chip 200 to pass therethrough to enter the wavelength conversion structure 300, and reflects the second light beam 302 from the wavelength conversion structure 300 back to the wavelength conversion structure 300.

Specifically, in this embodiment, the first light beam 202 emitted from the light emitting diode chip 200 passes through the filter 400 to enter the wavelength conversion structure 300. The wavelength conversion structure 300 then converts the first light beam 202 into the second light beam 302 with the second wavelength. A portion of the second light beam 302 leaves the light emitting diode package from its light emitting surface 502, and another portion of the second light beam 302 may propagate toward the light emitting diode chip 200 to reach the filter 400. The filter 400 can reflect a portion of the second light beam 302 back to the wavelength conversion structure 300, such that the portion of the second light beam 302 may pass through the wavelength conversion structure 300 and exit from the light emitting surface 502.

Therefore, since the filter 400 allows the first light beam 202 to pass therethrough, and reflects the second light beam 302, the filter 400 can prevent the second light beam 302 from entering the light emitting diode chip 200 which may absorb the second light beam 302, while the filter 400 does not block the first light beam 202 and allows the first light beam 202 to enter the wavelength conversion structure 300. Therefore, the light emitting diode package of this embodiment can prevent the wavelength conversion structure 300 from having a conversion efficiency loss, and can promote the total light emitting quantity of the light emitting diode package.

In this embodiment, the light emitting diode chip 200 can be a flip chip. In other words, electrodes (not shown) of the light emitting diode chip 200 can directly contact the lead frame 100 for electrically connections. Therefore, gold wires can be omitted, and the filter 400 and the wavelength conversion structure 300 can be disposed on the light emitting diode chip 200 in sequence.

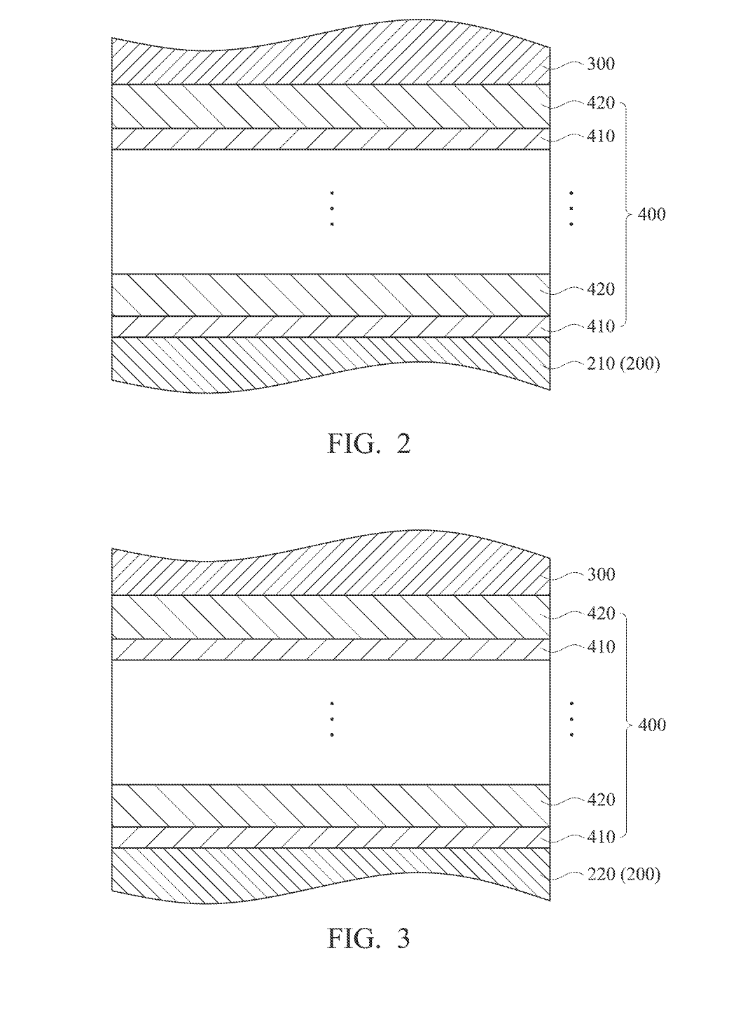

FIG. 2 is a locally enlarged diagram of the light emitting diode chip 200, the wavelength conversion structure 300, and the filter 400 shown in FIG. 1 according to one embodiment. Reference is made to FIG. 1 and FIG. 2. In this embodiment, the filter 400 is a distributed Bragg reflector (DBR). The distributed Bragg reflector includes a plurality of first dielectric layers 410 and a plurality of second dielectric layers 420 alternately stacked on each other. A reflective index of the first dielectric layers 410 is greater than a reflective index of the second dielectric layers 420. The distributed Bragg reflector is connected adjacent to the light emitting diode chip 200 via the first dielectric layer 410, and is connected adjacent to the wavelength conversion structure 300 via the second dielectric layer 420. The reflective index of the first dielectric layers 410 is greater than a reflective index of the light emitting diode chip 200, and the reflective index of the second dielectric layers 420 is smaller than a reflective index of the wavelength conversion structure 300.

In greater detail, since the reflective index of the first dielectric layers 410 is greater than the reflective index of the second dielectric layers 420, the first dielectric layers 410 and the second dielectric layers 420 can be stacked to form a periodic structure. The filter 400 can reflect the light within a specific wavelength range and allow the light within another specific wavelength range to pass therethrough by designing the thickness of each first dielectric layer 410 and each second dielectric layer 420. The first dielectric layers 410 and the second dielectric layers 420 are made of titanium dioxide (TiO₂), silicon dioxide (SiO₂), tantalum pentoxide (Ta₂O₅), silicon nitride (SiNₓ), or any combination thereof. However, the claimed scope of the invention is not limited to this respect.

In addition, since the first dielectric layer 410 is connected adjacent to the light emitting diode chip 200, and the reflective index of the first dielectric layer 410 is greater than the reflective index of the light emitting diode chip 200, the first light beam 202 emitted from the light emitting diode chip 200 can avoid the total internal reflection (TIR) when the first light beam 202 is incident the first dielectric layer 410 so as to prevent the first light beam 202 from being reflected back to the light emitting diode chip 200. Furthermore, since the second dielectric layer 420 is connected adjacent to the wavelength conversion structure 300, and the reflective index of the second dielectric layer 420 is smaller than the reflective index of the wavelength conversion structure 300, the first light beam 202 passing through the second dielectric layer 420 can avoid the total internal reflection when the first light beam 202 is incident to the wavelength conversion structure 300. In contrast, the second light beam 302 propagated from the wavelength conversion structure 300 to the second dielectric layer 420 of the filter 400 may be reflected back to the wavelength conversion structure 300 due to the total internal reflection so as to prevent the second light beam 302 from propagating to the light emitting diode chip 200.

In this embodiment, the light emitting diode chip 200 includes a sapphire substrate 210, and the reflective index of the first dielectric layer 410 is greater than a reflective index of the sapphire substrate 210. Since the sapphire substrate 210 is transparent, the first light beam 202 emitted from a luminous layer (not shown) of the light emitting diode chip 200 can pass through the sapphire substrate 210. In addition, since the first dielectric layer 410 is connected adjacent to the sapphire substrate 210, and the reflective index of the first dielectric layer 410 is greater than the reflective index of the sapphire substrate 210, the first light beam 202 propagated from the sapphire substrate 210 to the first dielectric layer 410 can avoid the total internal reflection so as to prevent the first light beam 202 from being reflected back to the light emitting diode chip 200.

However, the structure of the light emitting diode chip 200 is not limited to that of FIG. 2. FIG. 3 is a locally enlarged diagram of the light emitting diode chip 200, the wavelength conversion structure 300, and the filter 400 of FIG. 1 according to another embodiment. Reference is made to FIG. 1 and FIG. 3. In this embodiment, the light emitting diode chip 200 includes a gallium nitride layer 220, and the reflective index of the first dielectric layer 410 is greater than a reflective index of the gallium nitride layer 220. In greater detail, the sapphire substrate 210 (see FIG. 2) is removed, and the gallium nitride layer 220 originally being connected adjacent to the sapphire substrate 220 is exposed. In other words, the gallium nitride layer 220 can be connected adjacent to the first dielectric layer 410. The gallium nitride layer 220 may be an undoped gallium nitride buffer layer, or may be an n-doped gallium nitride layer. The claimed scope of the present invention is not limited in this respect. Therefore, the first light beam 202 propagated from the gallium nitride layer 220 to the first dielectric layer 410 can avoid the total internal reflection so as to prevent the first light beam 202 from being reflected back to the light emitting diode chip 200.

Reference is made to FIG. 1. In this embodiment, the first wavelength can be smaller than 500 nm, and the second wavelength can be greater than 500 nm. For example, the light emitting diode chip 200 can be a gallium nitride light emitting diode chip, in which the gallium nitride emits blue light, i.e., the first light beam 202 of which the wavelength is smaller than 500 nm. In addition, the wavelength conversion structure 300 may absorb the blue light and emit yellow light, i.e., the second light beam 302, in which the wavelength of the yellow light is greater than 500 nm. Therefore, the filter 400 can be designed to allow the light of which the wavelength is smaller than 500 nm to pass therethrough, and to reflect the light of which the wavelength is greater than 500 nm, so as to enhance the total light emitting quantity of the light emitting diode package.

In this embodiment, the light emitting diode package can further includes an encapsulant 500 covering the light emitting diode chip 200, the wavelength conversion structure 300, and the filter 400. The encapsulant 500 can prevent the covered elements from external damages, and the encapsulant 500 can be formed from transparent materials, such that the reduction of the total light emitting quantity of the light emitting diode package can be avoided. Moreover, a surface of the encapsulant 500 exposed from the lead frame 100 is the light emitting surface 502 of the light emitting diode package.

In this embodiment, the wavelength conversion structure 300 and the filter 400 together can be adhered on the light emitting diode chip 200. In greater detail, the wavelength conversion structure 300 can be first fabricated and then divided into a plurality of small pieces. After the filter 400 and an adhesive are adhered on the small piece of wavelength conversion structure 300, the small piece of wavelength conversion structure 300 is adhered on the light emitting diode chip 200. Since the thickness of the cured adhesive is very thin, the light emitting diode chip 200 can be considered as being connected adjacent to the filter 400. However, in other embodiments, the adhesive may be adhered on the light emitting diode chip 200 before adhering to the wavelength conversion structure 300, and the claimed scope of the present invention is not limited in this respect.

In this embodiment, the wavelength conversion structure 300 can include a main body 310 and a plurality of wavelength conversion particles 320 distributed in the main body 310. The wavelength conversion particles 320, which may be fluorescent powders such as inorganic fluorescent powders, can convert the first light beam 202 into the second light beam 302. Moreover, the main body 310 may be formed from a transparent material, such as silicon oxide inorganic compound, polycarbonate (PC), polyethylene terephthalate (PET), or any combination thereof.

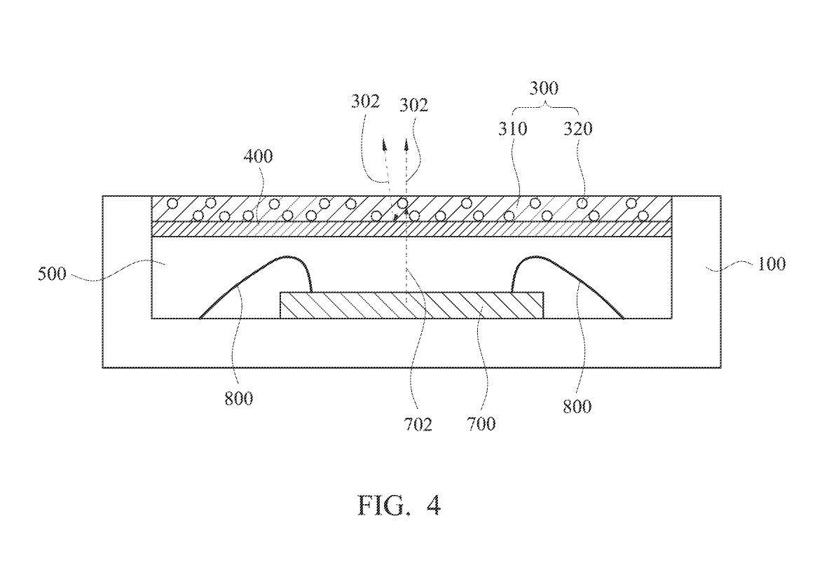

Reference is made to FIG. 4 which is a cross-sectional view of a light emitting diode package according to another embodiment of the present invention. The light emitting diode package includes a lead frame 100, a light emitting diode chip 700, an encapsulant 500, a wavelength conversion structure 300, and a filter 400. The light emitting diode chip 700 is disposed on and electrically connected to the lead frame 100. The light emitting diode chip 700 is configured to provide a first light beam 702 with a first wavelength. The encapsulant 500 covers the light emitting diode chip 700. The wavelength conversion structure 300 is disposed above the encapsulant 500 for converting the first light beam 702 into a second light beam 302 with a second wavelength. The filter 400 is disposed between the encapsulant 500 and the wavelength conversion structure 300. The filter 400 allows the first light beam 702 from the light emitting diode chip 700 to pass therethrough to enter the wavelength conversion structure 300, and reflects the second light beam 302 propagated from the wavelength conversion structure 300 back to the wavelength conversion structure 300.

Specifically, in this embodiment, the first light beam 702 emitted from the light emitting diode chip 700 passes through the filter 400 to enter the wavelength conversion structure 300. The wavelength conversion structure 300 then converts the first light beam 702 into the second light beam 302 with the second wavelength. A portion of the second light beam 302 may propagate toward the light emitting diode chip 700 to the filter 400. The filter 400 can reflect a portion of the second light beam 302 back to the wavelength conversion structure 300, such that the portion of the second light beam 302 can pass through and exit the wavelength conversion structure 300.

Therefore, since the filter 400 allows the first light beam 702 to pass therethrough, and reflects the second light beam 302, the filter 400 can prevent the second light beam 302 from entering the light emitting diode chip 200 which may absorb the second light beam 302, while the first light beam 702 enters the wavelength conversion structure 300 without being blocked by the filter 400. Therefore, the light emitting diode package of this embodiment can prevent the wavelength conversion structure 300 from having a conversion efficiency loss, and can promote the total light emitting quantity of the light emitting diode package.

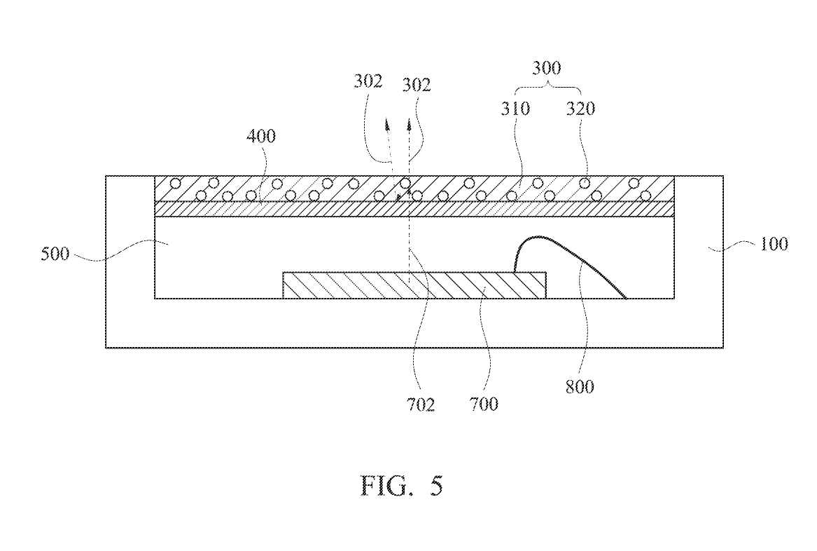

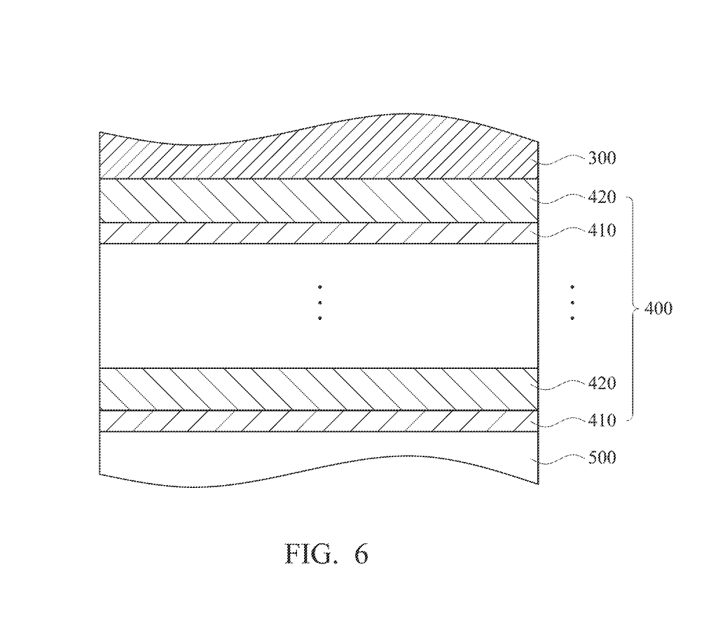

In this embodiment, the light emitting diode chip 700 can be a face up chip as shown in FIG. 4 or a vertical chip shown in FIG. 5. As shown in FIG. 4, the face up chip is bonded on the lead frame 100, and gold wires 800 are connected to two electrodes (not shown) of the face up chip and the lead frame 100. Moreover, as shown in FIG. 5, one electrode of the vertical chip is directly connected to the lead frame 100, and the other electrode of the vertical chip is connected to the lead frame 100 via a gold wire 800. In other words, in these two embodiments, the light emitting diode packages both include gold wire(s) 800, such that the wavelength conversion structure 300 and the filter 400 are disposed above the light emitting diode chip 700 in a remote mode.

FIG. 6 is a locally enlarged diagram of the encapsulant 500, the wavelength conversion structure 300, and the filter 400 of FIG. 4 or 5. In this embodiment, the filter 400 is a distributed Bragg reflector (DBR). The distributed Bragg reflector includes a plurality of the first dielectric layers 410 and a plurality of the second dielectric layers 420 alternately stacked on each other. A reflective index of the first dielectric layers 410 is greater than a reflective index of the second dielectric layers 420. The distributed Bragg reflector is connected adjacent to the encapsulant 500 via the first dielectric layer 410, and is connected adjacent to the wavelength conversion structure 300 via the second dielectric layer 420. The reflective index of the first dielectric layers 410 is greater than a reflective index of the encapsulant 500, and the reflective index of the second dielectric layers 420 is smaller than a reflective index of the wavelength conversion structure 300.

In greater detail, since the reflective index of the first dielectric layers 410 is greater than the reflective index of the second dielectric layers 420, the first dielectric layers 410 and the second dielectric layers 420 can be alternately stacked on each other to form a periodic structure. The filter 400 can reflect the light within a specific wavelength range and allow the light within another specific wavelength range to pass therethrough. The first dielectric layers 410 and the second dielectric layers 420 are formed from titanium dioxide (TiO₂), silicon dioxide (SiO₂), tantalum pentoxide (Ta₂O₅), silicon nitride (SiNₓ), or any combination thereof. However, the claimed scope of the present invention is not limited to this respect.

In addition, since the first dielectric layer 410 is connected adjacent to the encapsulant 500, and the reflective index of the first dielectric layer 410 is greater than the reflective index of the encapsulant 500, the first light beam 702 propagated from the encapsulant 500 can avoid the total internal reflection (TIR) when the first light beam 702 is incident to the first dielectric layer 410, so as to prevent the first light beam 702 from being reflected back to the light emitting diode chip 700. Furthermore, since the second dielectric layer 420 is connected adjacent to the wavelength conversion structure 300, and the reflective index of the second dielectric layer 420 is smaller than the reflective index of the wavelength conversion structure 300, the first light beam 702 passing through the second dielectric layer 420 can avoid the total internal reflection when the first light beam 702 is incident to the wavelength conversion structure 300. In contrast, the second light beam 302 propagated from the wavelength conversion structure 300 to the second dielectric layer 420 of the filter 400 may be reflected back to the wavelength conversion structure 300 due to the total internal reflection, so as to prevent the second light beam 302 from entering the light emitting diode chip 700.

Reference is made to FIG. 4 or 5. In this embodiment, the first wavelength can be smaller than 500 nm, and the second wavelength can be greater than 500 nm. For example, the light emitting diode chip 700 can be a gallium nitride light emitting diode chip, in which the gallium nitride emits blue light, i.e., the first light beam 702 of which the wavelength is smaller than 500 nm. In addition, the wavelength conversion structure 300 can emit yellow light, i.e., the second light beam 302, when the wavelength conversion structure 300 absorbs the blue light, in which the wavelength of the yellow light is greater than 500 nm. Therefore, the filter 400 can be designed to allow the light of which the wavelength is smaller than 500 nm to pass therethrough, and reflect the light of which the wavelength is greater than 500 nm, so as to enhance the total light emitting quantity of the light emitting diode package.

In this embodiment, the wavelength conversion structure 300 and the filter 400 can be adhered on the encapsulant 500 together. In greater detail, the wavelength conversion structure 300 can be first fabricated and then divided into a plurality of small pieces. After the filter 400 and an adhesive are adhered on the small piece of wavelength conversion structure 300, the small piece of wavelength conversion structure 300 is adhered on the surface of the encapsulant 500. Since the thickness of the cured adhesive is very thin, the encapsulant 500 can be considered as being connected adjacent to the filter 400. However, in other embodiments, the adhesive may be adhered on the surface of the encapsulant 500 before adhering to the wavelength conversion structure 300, and the claimed scope of the present invention is not limited in this respect.

In this embodiment, the wavelength conversion structure 300 can include a main body 310 and a plurality of wavelength conversion particles 320 distributed in the main body 310. The wavelength conversion particles 320, which may be fluorescent powders such as inorganic fluorescent powders, can convert the first light beam 702 into the second light beam 302. Moreover, the main body 310 may be a transparent material, such as silicon oxide inorganic compound, polycarbonate (PC), polyethylene terephthalate (PET), or any combination thereof.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode package, comprising:
a lead frame;
a light emitting diode chip disposed on and electrically connected to the lead frame for providing a first light beam with a first wavelength;
a wavelength conversion structure disposed on the light emitting diode chip for converting the first light beam into a second light beam with a second wavelength; and
a filter disposed between the light emitting diode chip and the wavelength conversion structure for allowing the first light beam from the light emitting diode chip to pass therethrough to enter the wavelength conversion structure, and reflecting the second light beam from the wavelength conversion structure back to the wavelength conversion structure.

2. The light emitting diode package of claim 1, wherein the light emitting diode chip is a flip chip.

3. The light emitting diode package of claim 2, wherein the filter is a distributed Bragg reflector (DBR), and the distributed Bragg reflector comprises a plurality of first dielectric layers and a plurality of second dielectric layers alternately stacked on each other, wherein a reflective index of the first dielectric layers is greater than a reflective index of the second dielectric layers, the distributed Bragg reflector is connected adjacent to the light emitting diode chip via the first dielectric layer, and the distributed Bragg reflector is connected adjacent to the wavelength conversion structure via the second dielectric layer, the reflective index of the first dielectric layers is greater than a reflective index of the light emitting diode chip, and the reflective index of the second dielectric layers is smaller than a reflective index of the wavelength conversion structure.

4. The light emitting diode package of claim 3, wherein the first dielectric layer and the second dielectric layer are formed from titanium dioxide (TiO₂), silicon dioxide (SiO₂), tantalum pentoxide (Ta₂O₅), silicon nitride (SiNₓ), or any combination thereof.

5. The light emitting diode package of claim 4, wherein the light emitting diode chip comprises a sapphire substrate, and the reflective index of the first dielectric layer is greater than a reflective index of the sapphire substrate.

6. The light emitting diode package of claim 4, wherein the light emitting diode chip comprises a gallium nitride layer, and the reflective index of the first dielectric layer is greater than a reflective index of the gallium nitride layer.

7. The light emitting diode package of claim 1, wherein the first wavelength is smaller than 500 nm, and the second wavelength is greater than 500 nm.

8. The light emitting diode package of claim 1, further comprising:
an encapsulant covering the light emitting diode chip, the wavelength conversion structure, and the filter.

9. The light emitting diode package of claim 8, wherein the wavelength conversion structure comprises:
a main body; and
a plurality of wavelength conversion particles distributed in the main body.

10. The light emitting diode package of claim 9, wherein the main body is made of silicon oxide inorganic compound, polycarbonate (PC), polyethylene terephthalate (PET), or any combination thereof.

11. A light emitting diode package, comprising:
a lead frame;
a light emitting diode chip disposed on and electrically connected to the lead frame for providing a first light beam with a first wavelength;
an encapsulant covering the light emitting diode chip;
a wavelength conversion structure disposed above the encapsulant for converting the first light beam into a second light beam with a second wavelength; and
a filter disposed between the encapsulant and the wavelength conversion structure for allowing the first light beam from the light emitting diode chip to pass therethrough to enter the wavelength conversion structure, and reflecting the second light beam from the wavelength conversion structure back to the wavelength conversion structure.

12. The light emitting diode package of claim 11, wherein the light emitting diode chip is a face up chip or a vertical chip.

13. The light emitting diode package of claim 12, wherein the filter is a distributed Bragg reflector (DBR), and the distributed Bragg reflector comprises a plurality of first dielectric layers and a plurality of second dielectric layers alternately stacked on each other, wherein a reflective index of the first dielectric layers is greater than a reflective index of the second dielectric layers, the distributed Bragg reflector is connected adjacent to the encapsulant via the first dielectric layer, and the distributed Bragg reflector is connected adjacent to the wavelength conversion structure via the second dielectric layer, the reflective index of the first dielectric layers is greater than a reflective index of the encapsulant, and the reflective index of the second dielectric layers is smaller than a reflective index of the wavelength conversion structure.

14. The light emitting diode package of claim 13, wherein the first and the second dielectric layers are made of titanium dioxide (TiO₂), silicon dioxide (SiO₂), tantalum pentoxide (Ta₂O₅), silicon nitride (SiNₓ), or any combination thereof.

15. The light emitting diode package of claim 11, wherein the first wavelength is smaller than 500 nm, and the second wavelength is greater than 500 nm.

16. The light emitting diode package of claim 11, wherein the wavelength conversion structure comprises:
a main body; and
a plurality of wavelength conversion particles distributed in the main body.

17. The light emitting diode package of claim 16, wherein the main body is formed from silicon oxide inorganic compound, polycarbonate (PC), polyethylene terephthalate (PET), or any combination thereof.
